(19) United States
(12) Patent Application Publication
(10) Pub. No.: US 2026/0074150 A1
(43) Pub. Date: Mar. 12, 2026

(54) PLASMA PROCESSING APPARATUS

(71) Applicants: Beijing E-Town Semiconductor Technology Co., Ltd., Beijing (CN); Mattson Technology, Inc., Fremont, CA (US)

(72) Inventors: Jianpin Zheng, Singapore (SG); Saikumar Kodumuri, Singapore (SG); Chian Siang Tan, Singapore (SG); Subrahmanyam Venkata Rama Kommisetti, Singapore (SG); Michael van Abbema, Singapore (SG); Ludovic Goffart, Singapore (SG); Darius Da Rui Sim, Singapore (SG)

(21) Appl. No.: 19/323,668

(22) Filed: Sep. 9, 2025

Related U.S. Application Data
(60) Provisional application No. 63/692,451, filed on Sep. 9, 2024.

(51) Int. Cl. H01J 37/32

(52) U.S. Cl. CPC H01J 37/32201; H01J 37/32311; H01J 37/3244; H01J 37/32458; H01J 37/32724; H01J 2237/002; H01J 2237/327

(57) ABSTRACT

A plasma processing apparatus is disclosed. The apparatus includes a processing chamber having a top and an interior space; a workpiece support in the processing chamber configured to support a workpiece; a plurality of microwave sources configured to generate a plasma in the processing chamber configured in the top of the processing chamber, each microwave source having a portion extending into the interior space of the processing chamber; and a gas distribution system configured to provide process gas to the processing chamber. Systems and methods for processing workpieces are also provided.

### CROSS REFERENCE TO PRIORITY APPLICATIONS

The present disclosure claims priority to U.S. Provisional Application Ser. No. 63/692,451, filed Sep. 9, 2024, the entirety of which is incorporated by reference herein.

### FIELD

The present disclosure relates generally to a plasma processing apparatus for plasma processing of a workpiece. More specifically, the present disclosure is directed to a plasma processing system including a microwave source.

### BACKGROUND

RF plasmas are used in the manufacture of devices such as integrated circuits, micromechanical devices, flat panel displays, and other devices. RF plasma sources used in modern plasma etch applications are required to provide a high plasma uniformity and a plurality of plasma controls, including independent plasma profile, plasma density, and ion energy controls. RF plasma sources typically must be able to sustain a stable plasma in a variety of process gases and under a variety of different conditions (e.g., gas flow, gas pressure, etc.). In addition, it is desirable that RF plasma sources produce a minimum impact on the environment by operating with reduced energy demands and reduced EM emission.

Problems with plasma processing can include processing uniformity and difficulty processing only certain portions of a workpiece while not processing or damaging other portions of the workpiece. For instance, for certain applications it may be desirable to etch/remove or deposit materials from or on the workpiece in a uniform manner. Additionally, for certain applications it would be desirable to be able to tune the plasma to address uniformity discrepancies. Accordingly, improved plasma processing apparatuses and systems are needed.

### SUMMARY

Aspects and advantages of embodiments of the present disclosure will be set forth in part in the following description, or may be learned from the description, or may be learned through practice of the embodiments.

Aspects of the present disclosure are directed to a plasma processing apparatus. The plasma processing apparatus includes a processing chamber having a top and an interior space; a workpiece support in the processing chamber configured to support a workpiece; a plurality of microwave sources configured to generate a plasma in the processing chamber configured in the top of the processing chamber, each microwave source having a portion extending into the interior space of the processing chamber; and a gas distribution system configured to provide process gas to the processing chamber.

Aspects of the present disclosure are directed to a processing system for processing a plurality of workpieces. The system includes a processing chamber having a top and an interior space; a workpiece support in the processing chamber configured to support a workpiece; a plurality of microwave sources configured to produce a plasma in the processing chamber configured in the top of the processing chamber, each microwave source having a portion extending into the interior space of the processing chamber; a gas distribution system configured to provide process gas to the processing chamber; and a controller configured to operate one or more of the workpiece support, the plurality of microwave sources, or the gas distribution system to implement a plasma treatment process.

Aspects of the present disclosure are directed to a method for processing a workpiece in a plasma processing apparatus. The method includes placing the workpiece on a workpiece support disposed in a processing chamber of the plasma processing apparatus; performing a plasma treatment process on the workpiece in the processing chamber. Performing the plasma treatment process includes generating a plasma in the processing chamber using a plurality of microwave sources disposed in a top of the processing chamber; and exposing the workpiece to the plasma.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art is set forth in the specification, which makes reference to the appended figures, in which:

FIG. 1 depicts a cross-sectional schematic view of an example plasma processing apparatus according to example embodiments of the present disclosure;

FIG. 2 depicts a top down view of a top of an example plasma processing apparatus according to example embodiments of the present disclosure;

FIG. 3 depicts a bottom up view of a top of an example plasma processing apparatus according to example embodiments of the present disclosure;

FIG. 4 depicts a perspective view of a bottom of an example plasma processing apparatus according to example embodiments of the present disclosure;

FIG. 5 depicts a cross-sectional view of an example microwave source for a plasma processing apparatus according to example embodiments of the present disclosure;

FIG. 6 depicts a cross-sectional view of an example microwave source for a plasma processing apparatus according to example embodiments of the present disclosure;

FIG. 7 depicts a cross-sectional schematic view of an example gas delivery tube for a plasma processing apparatus according to example embodiments of the present disclosure;

FIG. 8 depicts an enlarged view of a gas aperture pattern in a bottom view of an example plasma processing apparatus according to example embodiments of the present disclosure; and

FIG. 9 depicts a flow chart diagram of a method for processing a workpiece according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Aspects of the present disclosure are discussed with reference to a “workpiece,” “wafer” or semiconductor wafer for purposes of illustration and discussion. Those of ordinary skill in the art, using the disclosures provided herein, will understand that the example aspects of the present disclosure can be used in association with any semiconductor workpiece or other suitable workpiece. In addition, the use of the term “about” in conjunction with a numerical value is intended to refer to within ten percent (10%) of the stated numerical value. A “pedestal” refers to any structure that can be used to support a workpiece.

Conventional plasma processing apparatuses may include a processing chamber for treating one or more workpieces with plasma. Such chambers generally include a plasma generation source (e.g., an induction coil) disposed on or around at least a portion of the chamber. Current RF generators utilized to generate plasma with the induction coil can only be operated at fixed frequencies during processing and further require matching networks to match impedance. Additionally, current RF generators may have limited ability to change frequencies. Accordingly, it is difficult to tune the plasma in the processing chamber. Further, as devices on workpieces are shrinking, it is important for effective plasma processing with low workpiece damage. To reduce plasma damage, plasmas have been generated using pulsing technology to lower ion bombardment thus reducing damage to structure on the workpiece. Generating plasma using pulsing technology, however, is not an efficient use of power and energy and increases the cost to generate plasma and costs to operate plasma processing devices. Further, processing uniformity is also critical to ensure proper function and performance for workpieces.

According to examples of the present disclosure, a plasma processing apparatus is disclosed that includes a processing chamber, a workpiece support disposed in the processing chamber configured to support a workpiece during processing and a plurality of microwave sources in the top of the processing chamber having a portion extending into the interior space of the processing chamber. The microwave sources are configured to induce a plasma in the processing chamber. A gas distribution system for supplying process gas to the processing chamber is also provided. The microwave sources are configured to generate a low electron temperature species and high density plasma, which maximizes radical generation and minimizes ion bombardment thus decreasing plasma damage on the workpiece.

The plasma processing apparatus according to example embodiments of the present disclosure can provide numerous benefits and technical effects. For instance, plasma processing apparatus provides an efficient way to ignite and generate plasma, such as low electron temperature species plasma, reducing overall operational costs. Further, the plasma processing apparatus provides a plurality of microwave sources that can be individually controlled and tuned, thus providing for multi-zone tunability of the plasma within the processing chamber. Plasma density can be tuned in various zones to address any workpiece non-uniformity.

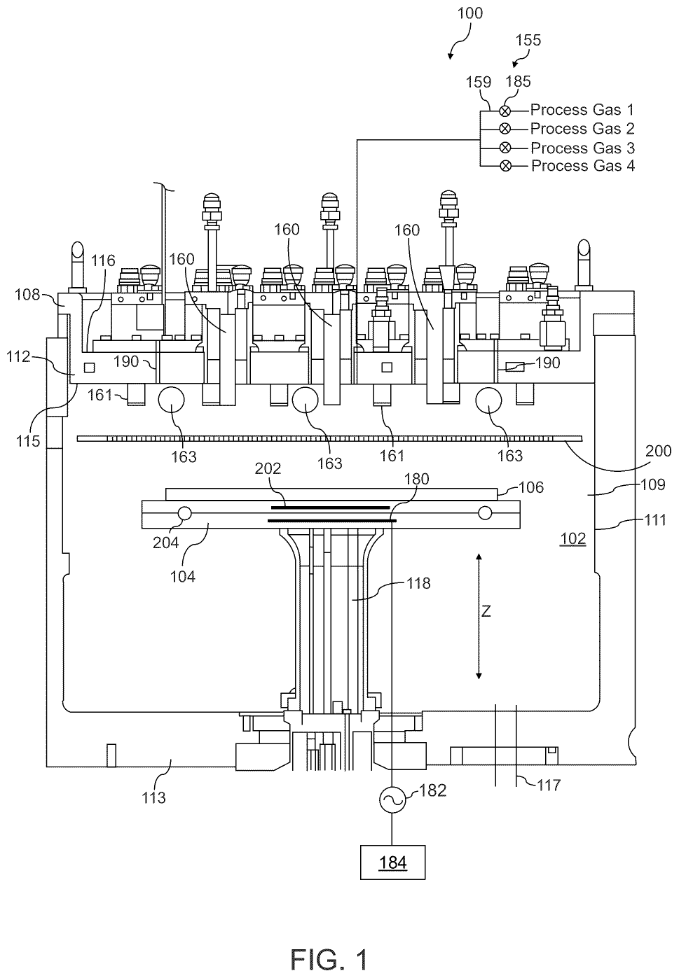

FIG. 1 depicts a plasma processing apparatus 100 according to an example embodiment of the present disclosure. The plasma processing apparatus 100 includes a processing chamber 109 defining an interior space 102. A workpiece support 104 (e.g., pedestal) is used to support a workpiece 106, such as a semiconductor wafer, within the interior space 102. Workpiece support 104 can include one or more support pins, such as at least three support pins, extending from workpiece support 104. (Not shown.) In some embodiments, workpiece support 104 can be spaced from the top 112 of the processing chamber 109. The processing chamber 109 includes one or more sidewalls 111, a top 112, and a bottom 113. The top 112 and/or bottom 113 can form a flat surface or can be curved or slightly domed. In embodiments, the top 112 has a concave portion 108 that extends into the interior space 102 of the processing chamber. The top 112 has a first surface 115 facing the interior space 102 of the processing chamber 109 and a second surface 116 (e.g., outer surface) opposite from the first surface 115 that faces externally. The sidewalls 111, top 112, and/or bottom 113 of the processing chamber 109 can be formed from a metal material or a coated metal material. For instance, the sidewalls 111, top 112, and/or bottom 113 can be formed from a metal material that is coated with a dielectric material. For instance, the surfaces of the sidewalls 111, top 112, and/or bottom 113 facing the interior space 102 can be coated with a dielectric material.

An exhaust 117 can be located about the bottom 113 of the processing chamber 109 and can be connected to a pump in order to maintain a desired vacuum environment or other desired pressure condition in the processing chamber 109. In some embodiments, the exhaust is located in a central location under the workpiece 106 and workpiece support 104. One or more vacuum pumps can be configured to maintain a vacuum and pressure control with valve (e.g., VAT throttle valve) in the processing chamber 109. Further, process gas flow in and out of the processing chamber 109 can be adjusted to achieve the desired vacuum pressure in the processing chamber 109. In embodiments, the vacuum pressure is from about 10⁻⁵ Torr to about 5 Torr, such as from about 10⁻³ Torr to about 4 Torr, such as from about 0.1 Torr to about 3 Torr. In some embodiments, the vacuum pressure is from about 0.05 Torr to about 1 Torr, from 0.3 Torr to about 0.8 Torr, from about 0.5 Torr to about 0.7 Torr. The exhaust 117 can also be utilized to evacuate process gas from the processing chamber 109. The vacuum pressure can be selected based on factors such as the desired process (e.g., etch or material deposition) and the workpiece materials.

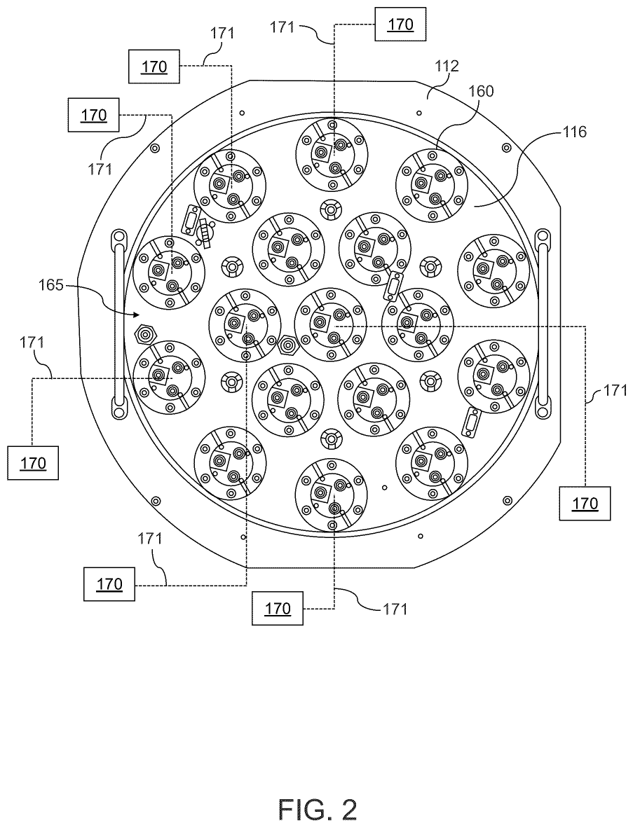

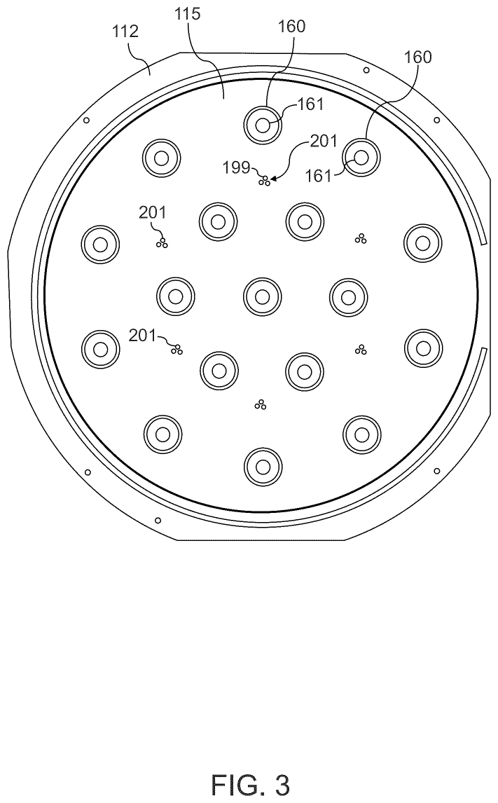

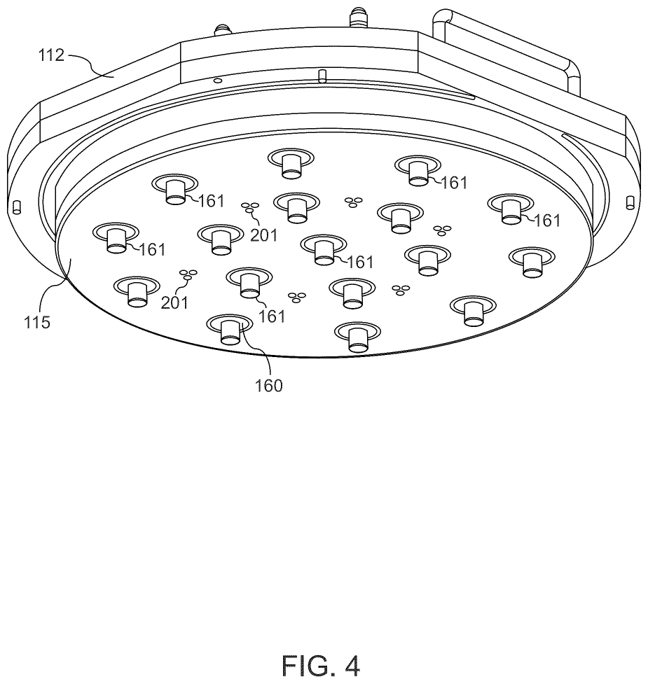

A plurality of microwave sources 160 are configured in the top 112 of the processing chamber 109. The plurality of microwave sources 160 can be disposed in a patterned array 165 in the top 112 of the processing chamber 109. FIGS. 2-4 depict disposition of the microwave sources 160 in a patterned array 165 configured in the top 112. In embodiments, the patterned array 165 can include any shape including circles, square, triangles, hexagons, etc. The microwave source 160 can be configured in the top 112 to provide microwave energy across the first surface 115 of the top 112 of the processing chamber 109. The total number of microwave sources 160 utilized can depend on the plasma area targeted for the processing chamber 109 and the targeted plasma density/tunability. In embodiments where it is desirable to process, for example, 300 mm workpiece, the number of microwave sources can be from about 1 to about 20. However, for processing smaller workpieces a smaller number of microwave sources can be utilized. Similarly, for processing larger workpieces, the number of microwave sources 160 can be increased. Any number of microwave sources 160 can be utilized in accordance with the present disclosure without departing from the scope described herein.

In certain embodiments, the microwave sources 160 can include a magnet portion 161 that extends into the processing chamber 109. The magnet portion 161 facilitates plasma generation in the plasma generation zone 163 within the processing chamber 109. However, it should be appreciated that other types of microwave sources 160 that do not include a magnet portion 161 extending into the processing chamber 109 can also be utilized in accordance with the present disclosure. Each microwave source 160 can each be coupled to a power generator 170 (e.g., microwave power generator) via a coaxial cable 171 as shown in FIG. 2. Each microwave source 160 can be coupled to different power generators 170. For instance, each microwave source 160 is coupled to an individual generator allowing for independent operation of each microwave source 160. Such a configuration allows for precision tunability of the plasma within and around each microwave source and such tunability can be utilized to address non-uniformity issues. Thus, in FIG. 2, seventeen independent power generators 170 are coupled independently to each microwave source 160. The power generators 170 can include solid-state generators to provide power to each microwave source 160. Each power generator can be operated at frequencies ranging from about 1 GHz to about 5 GHz, such as from about 2 GHz to about 4 GHz, such as from about 2.4 GHz to about 2.5 GHz. To tune the plasma, the use of the solid state power generators allows for the frequency of the power to be adjusted to facilitate plasma impedance matching. Accordingly, utilization of the solid-state power generator can eliminate the need for a matching network disposed between the power generator 170 and the microwave sources 160.

Utilization of independent power generators provides for plasma uniformity tuning within different regions of the processing chamber 109. For instance, local uniformity can be adjusted via adjusting the power supplied to different microwave sources 160. With respect to FIG. 2, the power supplied to one of the microwave sources 160 located in the center of the patterned array 165, can be independently modified in order to adjust any processing non-uniformity with respect one of the microwave sources 160 disposed on the outer perimeter of the patterned array 165. This allows for adjusting processing non-uniformity with respect to the center of the workpiece 106 versus the outer perimeter of the workpiece 106. Similarly, power generators 170 supplying power to one or more microwave sources 160 disposed on the outer perimeter of the patterned array 165 can be adjusted as compared to microwave sources 160 disposed on the inner portion of the patterned array 165 to address any perimeter non-uniformities.

Further, FIGS. 2-4 illustrate gas apertures 199 disposed in the first surface 115 of the top 112. The gas apertures 199 are disposed in an aperture pattern 201. As shown, the aperture pattern is triangular, however, any suitable shaped pattern can be utilized. The gas apertures 199 provide process gas from a gas delivery system 155 (shown in FIG. 1) to the interior space 102 of the process chamber 109. The gas apertures 199 and gas delivery system 155 are discussed further hereinbelow.

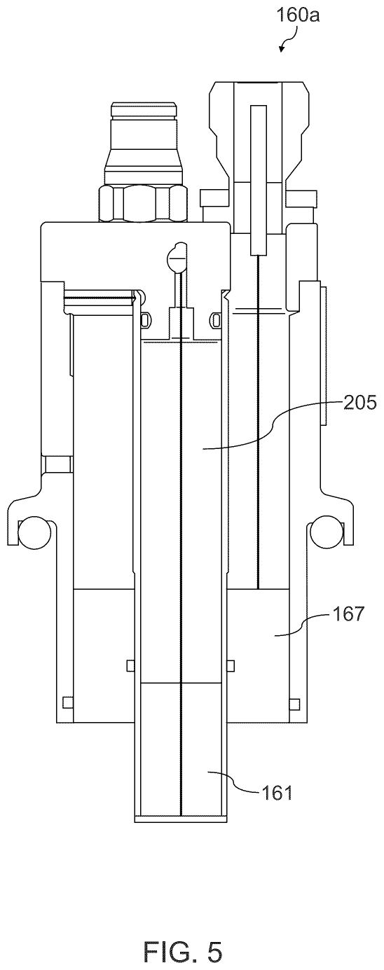

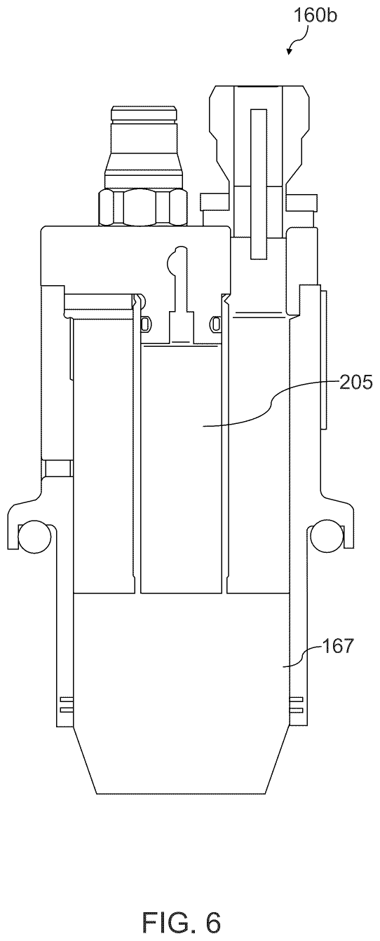

Referring now to FIGS. 5 and 6, two example microwave sources 160a and 160b are depicted. Both microwave sources 160a, 160b can be used in accordance with the present disclosure. For instance, as shown in FIG. 5, the microwave source 160a includes a magnet portion 161 that extends into the processing chamber 109 during processing, while FIG. 6 includes a microwave source 160b that does not have a magnet portion 161 extending therefrom. Specifically, microwave source 160a includes a ceramic base 167 which encircles at least a portion of the magnet portion 161. However, microwave source 160b does not include the magnet portion 161 and instead only includes the ceramic base 167. In certain embodiments, both types of microwave sources 160a, 160b can be disposed in the top 112 in a patterned array 165. In such embodiments, the different microwave sources 160a, 160b can be utilized depending on the operating pressure for the process recipe. For instance, for lower pressures (e.g., around 1 Torr or lower) the microwave sources 160a having the magnet portion 161 are utilized, whereas for operating at higher pressures (e.g., more than 1 Torr) microwave sources 160b are utilized. In such embodiments, the plasma processing apparatus 100 is configured with different types of microwave sources 160 in order to provide a plasma generated by a microwave source at different operating pressures. As noted, the microwave sources 160 can be configured to operate according to different operating pressures. In embodiments, certain of the plurality of microwave sources 160 can be configured to operate at pressure ranging from 10⁻⁵ mTorr to about 10⁻³ mTorr (e.g., microwave sources 160a), while certain other of the plurality of microwave sources 160 can be operated at operating pressures ranging from about 10⁻³ mTorr to about 10 mTorr (e.g., microwave sources 160b). In embodiments, the microwave sources 160 can include MODEL A microwave sources commercially available from Sairem-France.

Each of the microwave sources 160 can be fluid cooled. One or more conduits 205 can be disposed on the microwave sources 160, for instance, as shown in FIGS. 5-6 the conduits 205 are disposed around the microwave sources. In other embodiments, the conduits 205 can be disposed internally in the microwave sources 160. In other embodiments, it is contemplated that the conduits can be disposed on an external surface or surfaces of the microwave sources 160 (not shown). Fluid can be flowed through the conduits 205 to cool the microwave sources 160 either before, during, or after operation of the microwave sources 160. Suitable fluids can include liquids or gases, including, but not limited to coolant fluids, water, and combinations thereof. Cooling of the microwave sources 160 can facilitate operation of the microwave sources 160 at higher powers to generate plasma at high density without the risk of overheating and without the risk of sputtering of the microwave source material.

The microwave sources 160 are configured to produce plasma in the processing chamber having an electron temperature ranging from about 0.1 eV to about 5 eV, such as 0.5 eV to about 4.5 eV, such as from about 1 eV to about 4 eV, such as from about 1.5 eV to about 3.5 eV, such as from about 2 eV to about 3 eV. Thus, the plasma generated by the microwave sources 160 has lower electron temperature as compared to other plasmas generated by ICP or CCP processing. Generation and utilization of plasmas having the described electron temperatures allows for enhanced plasma treatment processes, including application of a gentler plasma having low electron temperatures while still maintaining a high plasma density improved efficiency during plasma treatment processes.

Given the configuration of the microwave sources 160, a high density plasma can be created in the plasma generation zone 163. By high density plasma, is meant a plasma having 1-2 orders of magnitude higher electron density as compared to a plasma generated by a capacitively coupled plasma source. For example, the microwave sources 160 can provide a plasma having an electron density of about 10¹⁰ cm⁻³ to about 10¹⁴ cm⁻³, such as about 10¹³ cm⁻³. Given the placement of the microwave sources 160 within the processing chamber, high-energy electrons make many collisions with the process gas, thus ionizing the process gas and generating more electrons. Radicals created by collisions with the electrons and ions can reach the workpiece 106, making the microwave sources 160 efficient producers of neutral radicals. Given the configuration of the microwave sources as described, high-density plasma can be generated due to the greatly enhanced probability of electron collisions within the plasma generation zone 163.

As shown in FIG. 1, according to example aspects of the present disclosure, the plasma processing apparatus 100 can include a gas delivery system 155 configured to deliver process gas to the processing chamber 109, for instance, via a gas distribution channel or other distribution system (e.g., showerhead). The gas delivery system 155 can include a plurality of feed gas lines 159. The feed gas lines 159 can be controlled using valves and/or gas flow controllers 185 to deliver a desired amount of gases into the processing chamber 109 as process gas. The gas delivery system 155 can be used for the delivery of any suitable process gas. As used herein “process gas” refers to any suitable gas and includes vapors. Example process gases include oxygen-containing gases (e.g., O₂, O₃, N₂O, H₂O), hydrogen-containing gases (e.g., H₂, D₂), nitrogen-containing gases (e.g., N₂, NH₃, N₂O), fluorine-containing gases (e.g., CF₄, C₂F₄, CHF₃, CH₂F₂, CH₃F, SF₆, NF₃), hydrocarbon-containing gases (e.g., CH₄), or combinations thereof. Other feed gas lines containing other gases can be added as needed. In some embodiments, the process gas can be mixed with an inert gas that can be called a “carrier” gas, such as He, Ar, Ne, Xe, or N₂. A gas flow controller 185 (e.g., mass flow controller(s)) can be used to control a flow rate of each feed gas line to flow a process gas into the processing chamber 109.

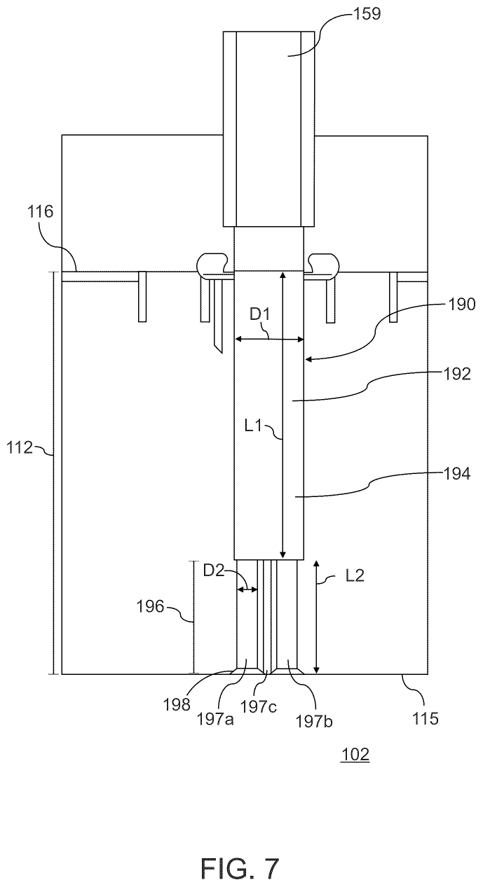

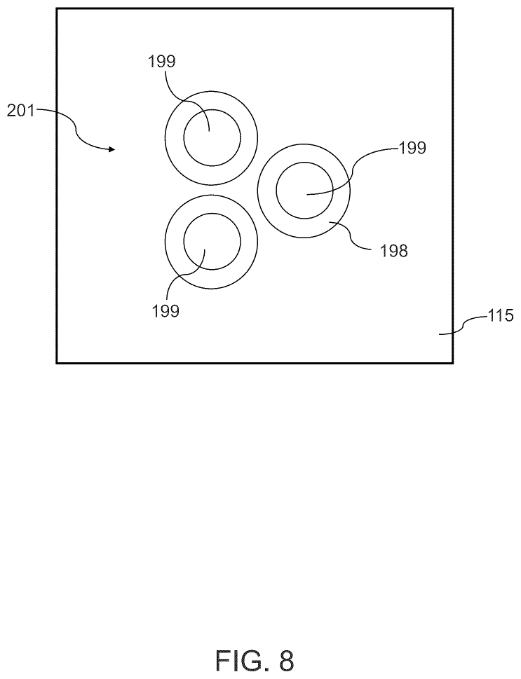

Referring to FIGS. 1-3 and 7, one or more gas delivery tubes 190 are configured through the top 112 of the processing chamber 109. Each gas delivery tube 190 disposed in the top 112 can fluidly coupled to the gas delivery system 155 such that process gas is provided into the interior space 102 of the processing chamber 109 via the gas delivery tubes 190. As shown in FIG. 7, the gas delivery tube 190 includes a first portion 192 (e.g., upper portion) comprised of a first conduit 194 having a first diameter D1. The first portion 192 of the gas delivery tube 190 is configured to receive process gas from one or more of the feed gas lines 159. As shown in FIG. 7, the first portion 192 can extend from the second surface 116 of the top 112 through at least a portion of the top 112. The gas delivery tube 190 includes a second portion 196 (e.g., lower portion) extending from the bottom of the first portion 192 to the first surface 115 of the top 112 that faces the interior space 102 of the processing chamber 109. The second portion 196 includes a plurality of conduits 197 each having a diameter D2. The diameter D2 of the plurality of conduits 197 is less than the diameter D1 of the first conduit 194 of the first portion 192. For instance, the ratio of the diameter D1 of the first conduit 194 to the diameter D2 is at least about 1.3:1 to about 20:1, such as from about 2:1 to about 15:1, such as from about 4:1 to about 10:1. As shown in FIG. 7, the plurality of conduits 197 includes three conduits 197a, 197b, and 197c. The conduits 197 are disposed such that they end in gas apertures 199 having a gradient opening 198 disposed in the first surface 115 of the top 112, as shown in FIG. 8. The aperture pattern 201 is a triangular pattern and three gas apertures 199 corresponding to three conduits 197 is shown. However, the disclosure is not so limited and any number of conduits 197 and gas apertures 199 can be utilized without departing from the scope of the present disclosure. The conduits 197 are disposed such that an aperture pattern 201 is provided in the top 112. Thus, as process gas flows through the gas delivery tube 190 the pressure of the process gas increases, such that it is delivered with a higher velocity from the gas apertures 199 as compared to the velocity upon delivery of the process gas to the first portion 192 of the gas delivery tube.

Referring back to FIG. 1, in embodiments, the plasma processing apparatus 100 can include a filtering grid 200. The filtering grid 200 can be used to perform ion filtering, plasma uniformity tuning, and/or UV light block from a mixture generated by plasma in the processing chamber 109 to generate a filtered mixture. The filtered mixture can be exposed to the workpiece 106 in the processing chamber 109. In some embodiments, the filtering grid 200 can be a multi-plate filtering grid.

In some embodiments, the filtering grid 200 can be made of metal (e.g., aluminum) or other electrically conductive material. In some embodiments, the filtering grid 200 can be made from either an electrically conductive material or dielectric material (e.g., quartz, ceramic, etc.). In some embodiments, filtering grid 200 can be made of other materials, such as silicon or silicon carbide. In the event the filtering grid 200 is made of metal or other electrically conductive material, the filtering grid can be grounded. For instance, suitable grounding components can be placed through the top 112 or the bottom 113 of the processing chamber 109 and electrically coupled to the filtering grid 200 to ground the filtering grid 200. (Not shown). In embodiments, the filtering grid 200 is grounded to prevent charging of the filtering grid 200 during workpiece processing.

In some embodiments, the filtering grid 200 can be configured to filter ions with an efficiency greater than or equal to about 90%, such as greater than or equal to about 95%. A percentage efficiency for ion filtering refers to the amount of ions removed from the mixture relative to the total number of ions in the mixture. For instance, an efficiency of about 90% indicates that about 90% of the ions are removed during filtering. An efficiency of about 95% indicates that about 95% of the ions are removed during filtering.

In some embodiments, the filtering grid 200 can be a multi-plate filtering grid. The multi-plate filtering grid can have multiple filtering grid plates in parallel. The arrangement and alignment of holes in the grid plate can be selected to provide a desired efficiency for ion filtering, such as greater than or equal to about 95%, plasma uniformity tuning, and/or UV light block to reach the workpiece 106. For instance, the filtering grid 200 can include a first grid plate and a second grid plate that are spaced apart in parallel relationship to one another. The first grid plate and the second grid plate can be separated by a distance.

The first grid plate can have a first grid pattern having a plurality of holes. The second grid plate can have a second grid pattern having a plurality of holes. The first grid pattern can be the same as or different from the second grid pattern. Charged particles can recombine on the walls in their path through the holes of each grid plate in the filtering grid 200. Neutral species (e.g., radicals) can flow relatively freely through the holes in the first grid plate and the second grid plate. The size of the holes and thickness of each grid plate can affect transparency for both charged and neutral particles.

Referring to FIG. 1, the workpiece support 104 can include a bias source having a bias electrode 180 in the workpiece support 104. The bias electrode 180 can be coupled to an RF power generator 184 via a suitable matching network 182. In some embodiments, the workpiece support 104 is configured such that a DC power can be applied to the workpiece 106. In some embodiments, DC power is applied to the bias electrode 180 located in the workpiece support 104. The DC power can be applied, either as a DC bias or a RF bias mode, to generate an electric field such that certain ion species can be attracted and/or accelerated towards the workpiece 106. With application of a DC power to the workpiece 106, the flux of certain ionic species can be controlled. This can facilitate ion assisted radical etching or densifying film deposition on the structure of the workpiece 106. In some embodiments, the DC power applied or provided to the bias electrode is from about 50 W to about 150 W. Further, in embodiments the bias electrode 180 can be used to chuck (e.g., hold) the workpiece 106 on the workpiece support 104 during processing. In other embodiments, additional electrodes can be included in the workpiece support 104 to chuck the workpiece 106 on the workpiece support 104. In certain other embodiments, the workpiece support 104 can be configured to generate a pressure gradient in order to hold the workpiece 106 on the workpiece support 104 during processing.

The workpiece support 104 can also be cooled. For instance, one or more cooling conduits 204 can be disposed in or on the workpiece support 104. Fluid can be flowed through the cooling conduits 204 to cool the workpiece support 104 either before, during, or after operation of the microwave sources 160. Suitable fluids can include liquids or gases, including, but not limited to coolant fluids, water, and combinations thereof. Cooling of the workpiece support 104 can facilitate operation of the plasma processing apparatus 100 and can reduce the risk of overheating and causing workpiece damage or non-uniformity.

The workpiece support 104 can also be heated. For instance, one or more heaters 202 can be disposed on or within the workpiece support. The heater 202 can be supplied with power to generate heat to heat both the workpiece support and the workpiece 106. For instance, heat generated by the heater 202 can heat the backside of the workpiece 106. The heater 202 can be configured to provide uniform workpiece heating across the workpiece surface. For instance, the heater 202 can be configured to provide even heating distribution and can minimize temperature variations across the workpiece 106.

Both the heater 202 and the cooling conduits 204 can be utilized for temperature control during the plasma treatment process. For instance, many plasma treatment processes may require precise temperature control during workpiece processing. Thus, both the heater 202 and cooling conduits 204 can be utilized to maintain specific workpiece processing temperatures during workpiece processing. Further, both the heater 202 and/or the cooling conduits 204 can be utilized to minimize workpiece 106 temperature fluctuations during processing. For instance, the heater 202 and/or cooling conduits 204 can be utilized to stabilize the temperature of the workpiece 106 during processing, including preventing thermal shocks that would negatively affect workpiece 106 performance. Further, having both the heater 202 and the cooling conduits 204 allows for different types of plasma treatment processes to be utilized within the plasma processing apparatus 100. For instance, different plasma treatment processes can require different workpiece processing temperatures. As such, use of the heater 202 and/or cooling conduits 204 can be used to adjust and control the workpiece temperature according to the specific plasma treatment process.

The workpiece support 104 can be movable in a vertical direction noted as “Z.” For instance, the workpiece support 104 can include a vertical lift 118 that can be configured to adjust a distance between the workpiece support 104 and the microwave sources 160. As one example, the workpiece support 104 can be located in a first vertical position for processing and can be in a second vertical position for placing a workpiece 106 on or removing a workpiece 106 from the workpiece support 104. The first vertical position can be closer to the filtering grid 200 or microwave sources 160 relative to the second vertical position.

In some embodiments, plasma processing apparatus 100 may include a controller. (Not Shown.) The controller may be configured to control the gas distribution system, the microwave sources, the workpiece support, cooling systems, and the DC power to implement a plasma treatment process. The controller can include one or more processors and one or more memory devices. The memory devices can store computer-readable instructions that when executed by the one or more processors cause the controller to control aspects of the plasma processing apparatus 100 to implement any of the methods disclosed herein. In some embodiments, the controller is configured to control the gas distribution system, the microwave sources, the workpiece support, cooling systems, and the DC power to implement a plasma treatment process (e.g., an etch process). The plasma treatment process may include certain operations. The operations may include admitting a process gas in the process chamber; providing microwave to the microwave sources to generate a plasma from the process gas to generate a first mixture, the first mixture comprising one or more first species; optionally, filtering the one or more first species to create a filtered mixture. In certain embodiments, the operations further include providing DC power to the bias electrode. The operations can further include modifying or adjusting the power of the microwave supplied to the microwave sources. The operations can further include modifying the amount or type of process gas supplied to the microwave sources in the processing chamber.

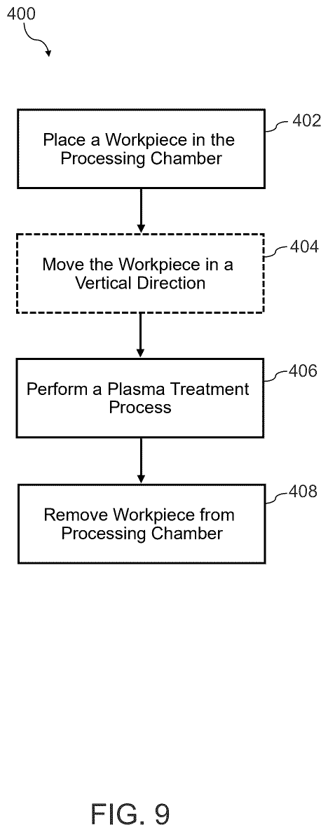

FIG. 9 depicts a flow diagram of one example method (400) according to example aspects of the present disclosure. The method (400) will be discussed with reference to the plasma processing apparatus 100 of FIGS. 1-8 by way of example. The method (400) can be implemented in any suitable plasma processing apparatus. FIG. 9 depicts steps performed in a particular order for purposes of illustration and discussion. Those of ordinary skill in the art, using the disclosures provided herein, will understand that various steps of any of the methods described herein can be omitted, expanded, performed simultaneously, rearranged, and/or modified in various ways without deviating from the scope of the present disclosure. In addition, various steps (not illustrated) can be performed without deviating from the scope of the present disclosure.

At (402), the method includes placing a workpiece 106 in the processing chamber 109 of a plasma processing apparatus 100. For instance, the workpiece 106 can be placed on a workpiece support 104 disposed in the processing chamber 109.

Optionally, at (404) the method can include moving the workpiece support 104 in a vertical direction to a processing position within the processing chamber 109. For instance, the workpiece support 104 having the workpiece 106 thereon can be moved to a position that is closer to the microwave sources 160 for plasma processing.

At (406), the method includes performing a plasma treatment process on the workpiece 106 in the processing chamber 109. The plasma treatment process can include a plasma etch treatment process, which can selectively remove one or more material layers from the workpiece 106. In other embodiments, the treatment process includes a plasma deposition process. For instance, the plasma deposition process can selectively deposit one or more material layers on the workpiece 106. Other plasma processes can be used to modify the material layers present on the workpiece. For example, plasma-based surface treatment processes can be utilized to modify the surface morphology of the workpiece 106 or to modify the chemical composition of layers on the workpiece 106. Any other, known suitable plasma-based processing for workpieces can be performed on the workpiece 106.

The plasma treatment process can include generating a plasma in the processing chamber 109 utilizing a plurality of microwave sources 160 disposed in the processing chamber 109 between the workpiece support 104 and the top 112 of the processing chamber 109.

In embodiments, the microwave sources 160 can include microwave source 160a, shown in FIG. 5, having a magnet portion 161 extending into the processing chamber 109. In other embodiments, the microwave sources 160 can include microwave sources 160b, as shown in FIG. 6, that do not include the magnet portion. The microwave sources 160a, 160b facilitate plasma generation in the plasma generation zone 163 within the processing chamber 109.

The microwave sources 160 can each be coupled to a power generator 170. Notably, separate and different power generators 170 can be coupled to each individual microwave source 160. The power generators 170 can include solid-state generators to provide power to each microwave source 160. To tune the plasma, the use of the solid state power generators allows for the frequency of the power to be adjusted to facilitate plasma impedance matching. During processing, power supplied to each microwave source 160 can be modified to adjust for processing non-uniformities. Further, during processing, the plasma generated in the plasma generation zone 163 can be tuned within different regions of the processing chamber 109. For instance, radial uniformity can be adjusted via adjusting the power supplied to different microwave sources 160.

Utilization of independent power generators 170 provides for plasma uniformity tuning within different regions of the processing chamber 109. For instance, local uniformity can be adjusted via adjusting the power supplied to different microwave sources 160. With respect to FIG. 2, the power supplied to one of the microwave sources 160 located in the center of the patterned array 165, can be independently modified in order to adjust any processing non-uniformity with respect one of the microwave sources 160 disposed on the outer perimeter of the patterned array 165. This allows for adjusting processing non-uniformity with respect to the center of the workpiece 106 versus the outer perimeter of the workpiece 106. Similarly, power generators 170 supplying power to one or more microwave sources 160 disposed on the outer perimeter of the patterned array 165 can be adjusted as compared to microwave sources 160 disposed on the inner portion of the patterned array 165 to address any perimeter or localized non-uniformities.

Referring back to FIGS. 5 and 6 depict two example microwave sources 160a, 160b that can be used in accordance with the present disclosure. For instance, as shown in FIG. 5, the microwave source 160a includes a magnet portion 161 that extends into the processing chamber during processing, while FIG. 6 includes a microwave source 160b that does not have a magnet portion 161 extending therefrom. In certain embodiments, both types of microwave sources 160a, 160b can be disposed in the top 112 in a patterned array 165. In such embodiments, the different microwave sources 160a, 160b can be utilized depending on the operating pressure for the process recipe. For instance, for lower pressures (e.g., around 1 Torr or lower) only the microwave sources 160a having the magnet portion 161 are utilized, whereas for operating at higher pressures (e.g., more than 1 Torr) only microwave sources 160b are utilized. In such embodiments, the plasma processing apparatus 100 is configured with different types of microwave sources 160 in order to provide a plasma generated by a microwave source at different operating pressures. As noted, the microwave sources 160 can be configured to operate according to different operating pressures. In embodiments, certain of the plurality of microwave sources 160 can be configured to operate at pressure ranging from 10⁻5 mTorr to about 10⁻3 mTorr (e.g., microwave sources 160a), while certain other of the plurality of microwave sources 160 can be operated at operating pressures ranging from about 10⁻3 mTorr to about 10 mTorr (e.g., microwave sources 160b).

The microwave sources 160 are configured to produce plasma in the processing chamber having an electron temperature ranging from about 0.1 eV to about 5 eV, such as 0.5 eV to about 4.5 eV, such as from about 1 eV to about 4 eV, such as from about 1.5 eV to about 3.5 eV, such as from about 2 eV to about 3 eV. Thus, the plasma generated by the microwave sources 160 has lower electron temperature as compared to other plasmas generated by ICP or CCP processing. Generation and utilization of plasmas having the described electron temperatures allows for enhanced plasma treatment processes, including improved efficiency during plasma treatment processes. Further, utilizing a plasma having the described electron temperature allows for further control over the distribution of reactive species and ions within the plasma, which can allow for more precise control over surface interactions between plasma species and the surface of the workpiece 106, leading to improved material performance of the workpiece 106.

Given the configuration of the microwave sources 160, a high density plasma can be created in the plasma generation zone 163. By high density plasma, is meant a plasma having 1-2 orders of magnitude higher of electron density as compared to a plasma generated by a capacitively coupled plasma source. For example, the microwave sources 160 can provide a plasma having an electron density of about 10¹⁰ cm⁻³ to about 10¹⁴ cm⁻³, such as about 10¹³ cm⁻³. Given the placement of the microwave sources 160 within the processing chamber, positive ions and high-energy electrons make many collisions with the process gas, thus ionizing the process gas and generating more electrons. Radicals created by collisions with the electrons and ions can escape, making the microwave sources 160 efficient producers of neutral radicals. Given the configuration of the microwave sources as described, high-density plasma can be generated due to the greatly enhanced probability of electron bombardment within the plasma generation zone 163.

Process gas can be delivered to the processing chamber 109 via a gas delivery system. The gas delivery system 155 can include a plurality of feed gas lines 159. The feed gas lines 159 can be controlled using valves and/or gas flow controllers 185 to deliver a desired amount of gases into the processing chamber 109 as process gas. The gas delivery system 155 can be used for the delivery of any suitable process gas. As used herein “process gas” refers to any suitable gas and includes vapors. Example process gases include oxygen-containing gases (e.g., O₂, O₃, N₂O, H₂O), hydrogen-containing gases (e.g., H₂, D₂), nitrogen-containing gases (e.g., N₂, NH₃, N₂O), fluorine-containing gases (e.g., CF₄, C₂F₄, CHF₃, CH₂F₂, CH₃F, SF₆, NF₃), hydrocarbon-containing gases (e.g., CH₄), or combinations thereof. Other feed gas lines containing other gases can be added as needed. In some embodiments, the process gas can be mixed with an inert gas that can be called a “carrier” gas, such as He, Ar, Ne, Xe, or N₂. A gas flow controller 185 (e.g., mass flow controller(s)) can be used to control a flow rate of each feed gas line to flow a process gas into the processing chamber 109.

One or more gas delivery tubes 190, configured through the top 112 of the processing chamber 109, can be utilized to provide gas from the gas delivery system 155 into the interior space 102 of the processing chamber 109. The gas delivery tubes 190 include a first portion 192 (e.g., upper portion) comprised of a first conduit 194 having a first diameter D1. The first portion 192 of the gas delivery tube 190 is configured to receive process gas from one or more of the feed gas lines 159. The gas delivery tube includes a second portion 196 extending from a bottom of the first portion 192 to the first surface 115 of the top that faces the interior space 102 of the processing chamber 109. The second portion 196 includes a plurality of conduits 197 each having a diameter D2. The diameter D2 of the plurality of conduits 197 is less than the diameter D1 of the first conduit 194 of the first portion 192. For instance, the ratio of the diameter D1 of the first conduit 194 to the diameter D2 is at least about 1.3:1 to about 20:1, such as from about 2:1 to about 15:1, such as from about 4:1 to about 10:1. The conduits 197 are disposed such that they end in gas apertures 199 having a gradient opening 198 disposed in the first surface 115 of the top 112. Thus, the conduits 197 are configured in gas aperture patterns 201 in the top 112 of the processing chamber 109. As process gas flows through the gas delivery tube 190 the pressure of the process gas increases, such that it is delivered into the processing chamber 109 at a higher velocity as compared to the gas velocity upon delivery of the process gas to the first portion 192 of the gas delivery tube 190.

Optionally, the method can include filtering one or more species in the plasma with a filtering grid 200 disposed between the microwave sources 160 and the workpiece 106 in the processing chamber 109. For instance, species generated in the plasma can pass through a filtering grid 200 to filter ions in the species. Neutral radicals passing through the filtering grid 200 are thus filtered to create a filtered mixture. The filtering grid 200 can be used to perform ion filtering, plasma uniformity tuning, and/or UV light block from a mixture generated by plasma in the processing chamber 109 to generate a filtered mixture.

In some embodiments, the filtering grid 200 can be configured to filter ions with an efficiency greater than or equal to about 90%, such as greater than or equal to about 95%. A percentage efficiency for ion filtering refers to the amount of ions removed from the mixture relative to the total number of ions in the mixture. For instance, an efficiency of about 90% indicates that about 90% of the ions are removed during filtering. An efficiency of about 95% indicates that about 95% of the ions are removed during filtering.

The method includes exposing the workpiece 106 to the plasma, such as exposing the workpiece 106 to radicals in the plasma or, where filtering is performed, exposing the workpiece 106 to the filtered mixture. For instance, exposure of the workpiece 106 to the plasma species can result in the removal of material from at least a portion of certain material layers present on the workpiece 106. When radicals are exposed to the workpiece, the radicals may etch material layers from the workpiece 106. In other embodiments, exposure of the workpiece 106 to the plasma species (e.g., radicals) can deposit a layer of material on the workpiece 106.

During exposure of the workpiece 106 to the plasma species the workpiece 106 is supplied with DC power via a DC bias to the bias electrode 180 in the workpiece support 104. Application of the DC power to the workpiece 106 may accelerate certain species from the plasma to the surface of the workpiece 106. For example, in some embodiments, application of the DC power to the workpiece 106 may result in accelerating certain etchant species, such as fluorine radical etchants, to the surface of the workpiece resulting in the removal of the material layer that is perpendicular to the flow of the one or more species of the plasma. In some embodiments, application of the DC power to the workpiece may result in accelerating certain deposition or layer forming species towards the surface of the workpiece resulting in the formation of additional layers or films on the workpiece 106.

At (408), the method can include removing the workpiece 106 from the processing chamber 109. Additional process steps can be performed prior to removing the workpiece from the processing chamber without deviating from the scope of the present disclosure. The workpiece 106 can be removed from workpiece support 104 in the processing chamber 109. To facilitate removal of the workpiece 106, the workpiece support 104 can be lowered to a non-processing position in the processing chamber 109. The workpiece 106 can be lifted from the surface of the workpiece support 104 and removed from the processing chamber 109 by a robot arm. The plasma processing apparatus can then be conditioned for future processing of additional workpieces.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A plasma processing apparatus, comprising:
a processing chamber having a top and an interior space;
a workpiece support in the processing chamber configured to support a workpiece;
a plurality of microwave sources configured to generate a plasma in the processing chamber configured in the top of the processing chamber, each microwave source having a portion extending into the interior space of the processing chamber, wherein one or more of the plurality of microwave sources comprises a magnet portion; and
a gas distribution system configured to provide process gas to the processing chamber.

2. The plasma processing apparatus of claim 1, wherein the top includes a concave portion extending into the processing chamber with the plurality of microwave sources configured within the concave portion.

3. The plasma processing apparatus of claim 1, wherein each of the microwave sources is coupled to different power generators.

4. (canceled)

5. The plasma processing apparatus of claim 1, wherein each of the microwave sources is individually controlled to adjust frequency and/or power.

6. (canceled)

7. The plasma processing apparatus of claim 1, wherein one or more of the microwave sources are configured to operate at pressures ranging from about 10⁻5 mTorr to about 10⁻3 mTorr.

8. (canceled)

9. The plasma processing apparatus of claim 1, wherein a plasma produced in the processing chamber has an electron temperature ranging from about 0.1 eV to about 5 eV.

10. The plasma processing apparatus of claim 1, comprising a filtering grid disposed between the plurality of microwave sources and the workpiece support.

11. (canceled)

12. The plasma processing apparatus of claim 1, wherein the gas distribution system comprises one or more gas delivery tubes configured through the top of the processing chamber, the one or more gas delivery tubes include an upper portion and a lower portion, the upper portion having a first diameter, the lower portion including a plurality of conduits, each of the conduits having a second diameter that is less than the first diameter.

13. (canceled)

14. (canceled)

15. (canceled)

16. The plasma processing apparatus of claim 1, wherein the plurality of microwave sources are located about 60 mm to about 160 mm from the workpiece when in a processing position.

17. (canceled)

18. A processing system for processing a plurality of workpieces, comprising:
a processing chamber having a top and an interior space;
a workpiece support in the processing chamber configured to support a workpiece;
a plurality of microwave sources configured to produce a plasma in the processing chamber configured in the top of the processing chamber, each microwave source having a portion extending into the interior space of the processing chamber, wherein one or more of the plurality of microwave sources comprises a magnet portion;
a gas distribution system configured to provide process gas to the processing chamber; and
a controller configured to operate one or more of the workpiece support, the plurality of microwave sources, or the gas distribution system to implement a plasma treatment process.

19. (canceled)

20. A method for processing a workpiece in a plasma processing apparatus, the method comprising:
placing the workpiece on a workpiece support disposed in a processing chamber of the plasma processing apparatus;
performing a plasma treatment process on the workpiece in the processing chamber including:
generating a plasma in the processing chamber using a plurality of microwave sources disposed in a top of the processing chamber, wherein one or more of the plurality of microwave sources comprises a magnet portion; and
exposing the workpiece to the plasma.

21. The plasma processing apparatus of claim 1, wherein one or more second microwave sources of the plurality of microwave sources do not include a magnet portion.

22. The plasma processing apparatus of claim 1, wherein the workpiece support comprises a bias source having a bias electrode coupled to a radio reference (RF) power generator.

23. The plasma processing apparatus of claim 1, wherein the workpiece support comprises a vertical lift configured to adjust a distance between the workpiece support and the plurality of microwave sources.

24. The plasma processing apparatus of claim 23, wherein the workpiece support is configured to move in a vertical direction.

25. The plasma processing apparatus of claim 1, wherein the gas distribution system comprises one or more gas apertures to provide a process gas, the one or more gas apertures arranged in aperture patterns positioned within interstitial spaces between the plurality of microwave sources.

26. The processing system of claim 18, wherein one or more second microwave sources of the plurality of microwave sources do not include a magnet portion.

27. The processing system of claim 18, wherein the workpiece support comprises a bias source having a bias electrode coupled to a radio reference (RF) power generator.

28. The processing system of claim 18, wherein the gas distribution system comprises one or more gas apertures to provide a process gas, the one or more gas apertures arranged in aperture patterns positioned within interstitial spaces between the plurality of microwave sources.

29. The method of claim 20, wherein one or more second microwave sources of the plurality of microwave sources do not include a magnet portion.

30. The method of claim 20, wherein the workpiece support comprises a bias source having a bias electrode coupled to a radio reference (RF) power generator.

31. The method of claim 20, wherein the gas distribution system comprises one or more gas apertures to provide a process gas, the one or more gas apertures arranged in aperture patterns positioned within interstitial spaces between the plurality of microwave sources.
